(19) United States
(12) Patent Application Publication
(10) Pub. No.: US 2005/0029905 A1
(43) Pub. Date: Feb. 10, 2005

(54) DEVICE FOR CONTROLLING AN ELECTRONICALLY-MONITORED ULTRASONIC PIEZOELECTRIC ACTUATOR, AND METHOD FOR USING THE SAME

(75) Inventors: Arnaud Dal, Versailles (FR); Christophe Ripoll, Viroflay (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: RENAULT S.A.S, Boulogne-Billancourt (FR)

(21) Appl. No.: 10/494,529

(22) PCT Filed: Nov. 22, 2002
(86) PCT No.: PCT/FR02/04013

(30) Foreign Application Priority Data
Nov. 22, 2001 (FR) 01/15125

(51) Int. Cl. H01L 41/09

(52) U.S. Cl. 310/317

(57) ABSTRACT

The invention concerns a device for controlling an ultrasonic piezoelectric actuator, electronically monitored from a computer controlling a continuous current voltage source. The invention is characterized in that it comprises a DC to DC converter, powered by the voltage source, delivering at least in output a direct current voltage (Vs) between two end terminals (B1, B2) parallel to which is connected at least an arm, consisting of two alternately controllable series-connected bridge switches and whereof the midpoint is alternately connected to the two output terminals of the DC to DC converter by a load consisting of at least an actuator in series with a resonance inductor.

The present invention relates to a device for operating electronically driven ultrasonic piezoelectric actuators, and more particularly fuel injectors that have a piezoelectric stage and that are driven by the electronic injection computer of an internal combustion engine in a motor vehicle. It also relates to a method for use of the said device.

More precisely, the problem that the invention is intended to solve is the excitation of piezoelectric cells to cause vibration of the structure of an injector described in French Patent Application No. 99-14548, filed in the name of the Applicant. This type of injector is intended to atomize the fuel very finely into droplets that have the specific size to assure precise dosing and that are sufficiently small to assure complete and homogeneous vaporization of the injected fuel. Such an injector is provided with, among other parts, a cylindrical nozzle fed with fuel and having at its end an injection orifice, and with means for causing cyclic vibration of the nozzle, such as a transducer provided with a piezoelectric ceramic stage, at the terminals of which the electric voltage is varied within a scaling ratio in order to modify its thickness between two extreme positions corresponding to opening and closing of the injector. An injector piezoelectric ceramic is equivalent on the first order to a capacitance having high charging voltage, in excess of one hundred volts. This transducer is driven time-wise and intensity-wise by the engine's electronic control system in order to achieve oscillating opening of the nozzle tip at ultrasonic frequency.

The purpose of the present invention is to generate a high-frequency alternating signal to excite the piezoelectric cells from a direct-current voltage source. In a motor vehicle, the battery or alternator delivers a supply voltage having a value of 12 or 42 volts, which entails stepping up this voltage with a DC-to-DC voltage stepup converter.

To this end, a first object of the invention is a device for operating at least one ultrasonic piezoelectric actuator, which is driven electronically from a control computer and a direct-current voltage source, characterized in that it is provided with a DC-to-DC converter that is fed by the voltage source and that delivers at least one direct-current output voltage between two end terminals, in parallel with which there is connected at least one bridge arm composed of two alternately operable switches in series, the midpoint of the arm being connected alternately to the two output terminals of the DC-to-DC converter via a load composed of at least one actuator in series with a resonance inductor.

According to another characteristic of the invention, the DC-to-DC converter delivers a single direct-current output voltage between the two end terminals, and at least one first bridge arm of the operating device, composed of two alternately operable bridge switches in series, is connected in parallel across the output voltage, the midpoint of the said arm being connected via a load composed of at least one actuator in series with a resonance inductor to the midpoint of at least one second bridge arm, composed of two alternately operable bridge switches and mounted in parallel with the first arm.

According to another characteristic of the invention, wherein the DC-to-DC converter delivers a single direct-current output voltage, the operating device is provided with a first bridge arm, composed of two alternately operable switches and connected in parallel with the output terminals of the converter, the midpoint of the said arm being connected to the midpoint of a second bridge arm, composed of two alternately operable switches and mounted in parallel with the first arm, via a load comprising four actuators in parallel, connected alternately to a resonance inductor.

According to another characteristic of the invention, wherein the DC-to-DC converter delivers a single direct-current output voltage, the operating device is provided with at least one first bridge arm, composed of two alternately operable switches, and with at least two second bridge arms, each composed of two alternately operable switches and mounted in parallel with the first arm between the two end terminals of the converter, such that the midpoint of each first arm is connected to the midpoint of at least one second arm via a load comprising at least one actuator connected to a resonance inductor.

According to another characteristic of the invention, the DC-to-DC converter delivers two direct-current output voltages between a common reference terminal and two end terminals, in parallel with which there is connected at least one bridge arm, composed of two alternately operable switches, the midpoint of the said arm being connected to the reference terminal via a load comprising at least one actuator in series with a resonance inductor.

According to another characteristic of the invention, wherein the DC-to-DC converter delivers two direct-current output voltages, it is provided with four first bridge arms, each composed of two alternately operable bridge switches (P₁ᵢ, P₂ᵢ) mounted in parallel between the two end terminals (B₁, B₂), the midpoint (Jᵢ) of the said arms being connected to the reference terminal (Bₒ) via a load composed of an actuator (Iᵢ) in series with a resonance inductor (Lᵢ).

A second object of the invention is a method for use of a device for operating at least one ultrasonic piezoelectric actuator, composed of a bridge assembly, characterized in that, for operation of a given actuator, the control computer on the one hand causes selection means connected to the said actuator to close and on the other hand, in a first phase, causes a first pair of bridge switches composed of a first switch of a first bridge arm and of a second switch of a second bridge arm to close and simultaneously the second pair formed from the other two switches of the said arms to open and, in a second phase, the said four switches to change over to an inverse position, in such a way as to obtain a sinusoidal voltage at the terminals of the oscillating circuit formed by the said actuator and the associated resonance inductor, these two phases being repeated a specified number of times during the period of functioning of the actuator in order to generate a high-voltage, high-frequency signal at the piezoelectric actuator from the direct-current voltage source.

According to another characteristic of the invention, for operation of a given actuator, the control computer on the one hand causes selection means connected to the said actuator to close and on the other hand, in a first phase, a first switch of a first bridge arm to close and simultaneously the second bridge switch to open and, in a second phase, the said two switches to change over to an inverse position, in such a way as to obtain a sinusoidal voltage at the terminals of the oscillating circuit formed by the said actuator and the associated resonance inductor, these two phases being repeated a specified number of times during the period of functioning of the actuator in order to generate a high-voltage, high-frequency signal at the piezoelectric actuator from the direct-current voltage source.

Other characteristics and advantages of the invention will become apparent upon reading the description of several embodiments of a device for operating a piezoelectric actuator, illustrated by the following figures, wherein:

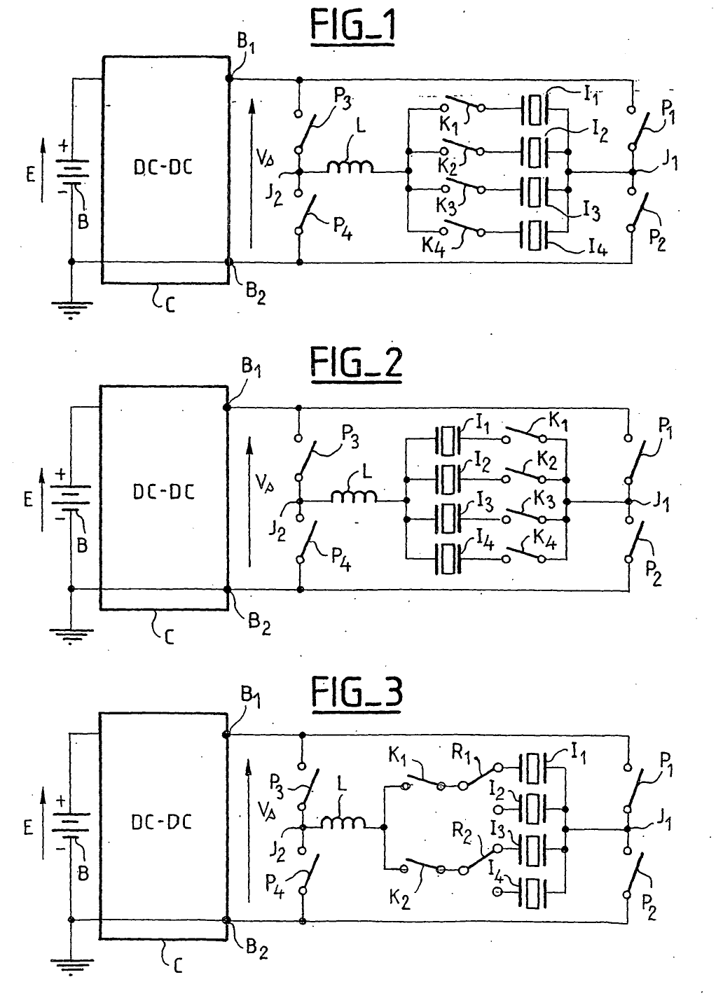

FIGS. 1 to 6 show the electronic diagram of several embodiments of an inventive operating device, according to a first structure having a DC-to-DC converter that delivers a single output voltage;

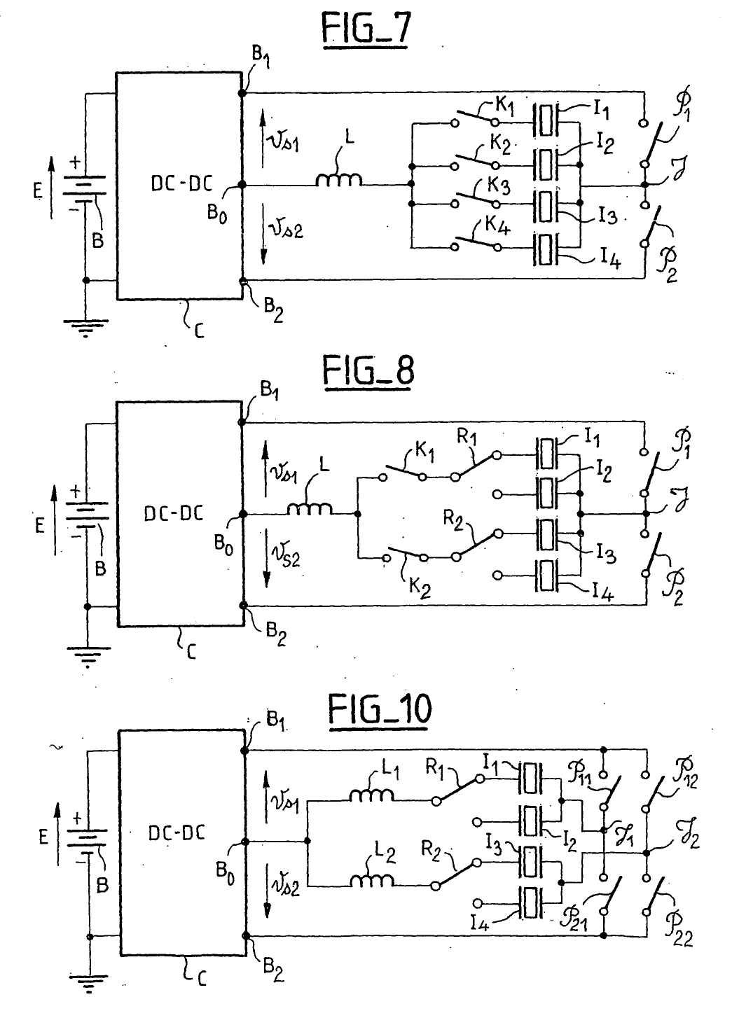

FIGS. 7 to 11 show the electronic diagram of several embodiments of an inventive operating device, according to a second structure having a DC-to-DC converter that delivers two output voltages.

For these non-limitative practical examples, elements denoted by like reference numerals on the different figures perform like functions in view of like results.

Since the invention comprises generating a sinusoidal signal having a high voltage greater than one hundred volts and a high frequency greater than ten kilohertz at the piezoelectric cell of each fuel injector of a vehicle from a direct-current source, or in other words the battery, it proposes different topologies of the device for operating an actuator for assuring excitation of the said piezoelectric ceramics through an inductor in order to compose a resonant circuit. These structures are valid for 1 to N injectors, where N is an integral number, preferably equal to 4, 5, 6, 8, 10 or 12. By way of non-limitative example, the number of operated injectors in the description hereinafter is 4.

All the topologies described represent structures having a DC-to-DC converter fed by the direct-current voltage source and delivering one or two direct-current output voltages.

According to a first structure, the DC-to-DC converter has a single output between two end terminals B₁ and B₂, delivering a direct-current high voltage Vs. As shown by the diagram of a first embodiment in FIG. 1, the device for operating one of 4 piezoelectric actuators Iᵢ, where i is an integral number varying from 1 to 4, is provided with a source B of direct-current voltage E—such as a battery—between the terminals of which there is connected a DC-to-DC converter, the (−) terminal of the voltage source further being electrically grounded. Terminals B₁ and B₂ may or may not be mounted at floating potential relative to the battery and, in the examples described, terminal B₂ is connected to the (−) terminal of the battery. Between the end terminals B₁ and B₂ of converter C, which delivers a direct-current high-voltage Vₛ greater than E, there are connected a first and a second bridge arm, each composed of two alternately operable bridge switches in series, P₁ and P₂ on the one hand and P₃ and P₄ on the other hand, and such that the midpoint J₁ of the first is connected to the midpoint J₂ of the second by a load composed of at least one actuator in series with a resonance inductor L.

In the case of an internal combustion engine of a motor vehicle requiring four injectors, the diagram illustrates four piezoelectric ceramic actuators I₁, . . . , Iᵢ, . . . , I₄, which are mounted in parallel and, according to a first alternative version of the first embodiment, are chosen successively by virtue of an operable selection switch Kᵢ mounted in series with each of them. In the case of injectors having single electrical isolation, or in other words where one of the two electrodes of the piezoelectric cell is connected to the metal frame or to a fixed potential, one of their terminals is connected to the frame. As a function of the piezoelectric injector that must be open during the intervals of activity to assure that the corresponding cylinder of the engine is fed with fuel, switch Kᵢ is operated by a logic signal originating from the injection computer, in order that the high-voltage output vₛ of the converter is connected to precisely that injector.

In the case of injectors having piezoelectric cells with double isolation, or in other words where the two electrodes of each cell are isolated from the metal frame, it is also possible to invert injectors Iᵢ and selection switches Kᵢ in the oscillating circuit of the actuator. As shown by the diagram of a second version of the first embodiment in FIG. 2, where the injectors are doubly isolated, they can therefore have one of their terminals connected directly to resonance inductor L, and switches K₁ to K₄ have one of their terminals connected to the frame.

The functioning of this operating circuit is as follows, as a function of the operation of the different switches. In a first phase, the operating signal transmitted by the injection computer on the one hand causes selection switch Kᵢ connected to the chosen injector Iᵢ, to close and on the other hand a first pair of bridge switches composed of a first switch P₂ of the first arm and of a second switch P₃ of the second arm to close simultaneously, thus connecting midpoint J₁ of the first arm to terminal B₂ of converter C and midpoint J₂ of the second arm to terminal B₁ thereof. Simultaneously, the second pair formed by the other two switches of the said arms is operated such that these switches open. During this time interval, the voltage v₂ at the terminals of the resonant circuit composed of resonance inductor L and actuator Iᵢ is positive, with a maximum value equal to +Vₛ. Then, in a second phase, the signal operates switches P₃ and P₂ such that they open and simultaneously operates the two switches P₁ and P₄ such that they close, thus connecting midpoint J₁ of the first arm to terminal B₁ of converter C and midpoint J₂ of the second arm to terminal B₂ thereof. Thus voltage v₂ at the terminals of the resonant circuit becomes negative, with a maximum value equal to −Vₛ. These two phases are repeated a large number of times during the injection period, which ranges from 100 μs to 8 ms. Voltage v_{ci} at the terminals of injector Iᵢ is then a high-voltage, high-frequency sinusoidal signal, oscillating between a maximum value and a minimum value. The injection computer then successively operates the other injectors Iᵢ mounted in parallel, in the order specified for the functioning of an internal combustion engine.

According to a second embodiment, illustrated by the diagram of FIG. 3, the four injectors Iᵢ are connected in pairs by relays R₁ and R₂ respectively, each connected to one terminal of selection switches K₁ and K₂ respectively, the other terminal of which is connected to resonance inductor L, which is intended to compose an oscillating circuit with each injector in succession. The injection computer first acts on the relays then simultaneously the selection and bridge switches in order to select the injector to be operated.

The functioning of the operating device is as follows. For excitation of injector I₁, the computer first causes the means for selection of the injector, or in other words relay R₁, to turn off relative to injector I₁ when relay R₂ is in off position, and also causes switch K₁ to close and switch K₂ to open for the purpose of connecting actuator I₁ to resonance inductor L. Then it simultaneously causes, in a first phase, bridge switch P₂ of the first arm to close and bridge switch P₃ of the second arm to open, while the other switches P₁ and P₄ are open. In a second phase, the computer causes the four switches to change over to the inverse position. Thus the voltage v_{c1} at the terminals of actuator I₁ is a sinusoidal signal oscillating between the extreme values +Vs and −Vs, while the three other injectors do not receive any voltage. The duration T_{Ki} of closing of each selection switch corresponds to the injection time, which can vary between 100 μs and 5 ms for a four-injector engine. The period T_{Pi} of the sinusoidal signal v₂ at the terminals of the oscillating circuit formed by the actuator and the associated resonance inductor depends exclusively on the structure of the injectors, the resonance frequency F_{Pi} varying between 10 kHz and 1 MHz.

Since relay R₂ is already in off position, the excitation of actuator I₃ is achieved by opening selection switch K₁ and closing switch K₂, so that the voltage v₂ at the terminals of the oscillating circuit composed of inductor L and injector I₃ causes resonance thereof. The voltage signal v_{c3} at the terminals of injector I₃ is a high-voltage, high-frequency sinusoidal signal between the following instants.

Since the switching of a relay from off position to on position takes longer than the opening or closing of a switch, the computer causes first relay R₁ to switch to on position for the purpose of being able to excite injector I₂ in the following instant. Then relay R₁ is switched to on position while relay R₂ is still switched to off position relative to injector I₃, and simultaneously switch K₂ is closed while switch K₁ is open. And so on for the four actuators.

As in the foregoing, it is possible in an alternative embodiment to invert the position of the actuators with that of the selection means when they have double galvanic isolation, such that one of their terminals is connected directly to the inductor.

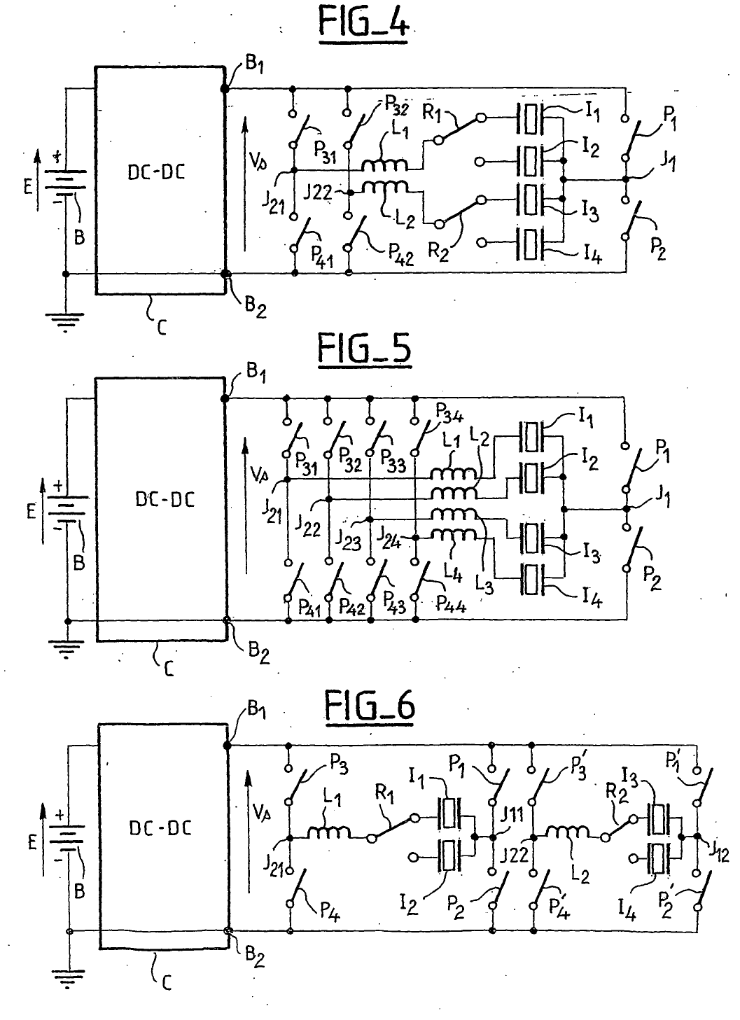

According to a third embodiment, illustrated in the diagram of FIG. 4, wherein the DC-to-DC converter delivers a single direct-current output voltage Vₛ, the operating device is provided with a first arm, composed of two alternately operable bridge switches P₁ and P₂ in series, and with two alternately operable second arms, each of which is composed of two bridge switches P₃ⱼ, P₄ⱼ in series and is mounted in parallel with the first arm between the two end terminals B₁ and B₂ of converter C, where j is an integral number varying from 1 to 2. Midpoint J₁ of the first arm is connected to midpoint J₂ⱼ of each second arm via a load composed of a group of two actuators I₁ and I₂ on the one hand and I₃ and I₄ on the other hand, each connected to a resonance inductor L₁ and L₂ respectively.

In the precise case of FIG. 4, the load connecting the two midpoints J₁ of the first arm to J₂ⱼ of a second arm is composed of a pair of actuators I₁ and I₂, I₃ and I₄ in parallel, connected to relays R₁ and R₂ respectively, in turn connected to resonance inductors L₁ and L₂ respectively.

In an alternative version of this embodiment, the load connecting the midpoint of the first arm to that of one of the second arms mounted in parallel is composed of two actuators mounted in parallel, such as I₁ and I₂, I₃ and I₄, and each connected to an operable selection switch Kᵢ, where i is an integral number varying from 1 to 4, itself connected to a resonance inductor Lᵢ.

The functioning of this operating device depends on the injection computer, which successively acts on the relays or the selection switches in such a way that the voltage obtained from voltage source B is sufficient to achieve excitation, by an alternating square-wave voltage, of the oscillating circuit that is formed by injector Iᵢ and the associated resonance inductor and is driven by the computer.

The fourth embodiment, illustrated in FIG. 5, relates to an inventive operating device, which comprises a DC-to-DC converter delivering a single direct-current output voltage Vₛ, and which is provided on the one hand with a first arm, mounted in parallel between the two end terminals B₁, B₂ of the converter and composed of two alternately operable bridge switches P₁, P₂ in series, and on the other hand four second arms, each composed of two bridge switches P₃ᵢ, P₄ᵢ respectively in series, where i is an integral number varying from 1 to 4. Midpoint J₁ of the first arm is connected to midpoint J₂ᵢ of a second arm via a load composed of an actuator Iᵢ connected to a load inductor Lᵢ.

The functioning of the device is driven by the injection computer which, before exciting an actuator Iᵢ, for example, operates switch P₂ of the first arm and switch P₁ᵢ of the second arm connected to actuator Iᵢ, such that they close and simultaneously operates switch P₁ of the first arm and switch P₄ᵢ of the second arm such that they open in a first phase, then in a second phase it inverts the operation of the said switches to deliver an exciting voltage to the oscillating circuit composed of actuator Iᵢ and its associated resonance inductor Lᵢ. These two phases are repeated a specified number of times during the injection period.

According to the fifth embodiment of the inventive operating device, illustrated by the diagram of FIG. 6, in which the DC-to-DC converter again delivers a single direct-current output voltage Vₛ, the device is provided with two first arms, mounted in parallel between the two end terminals B₁, B₂ of converter C and composed of two alternately operable bridge switches P₁, P₂ and P₁′, P₂′ in series, and with two second arms, composed of two bridge switches P₃, P₄ and P₃′, P₄′ respectively in series. These arms are such that the midpoint J₁₁ and J₁₂ of each of the first arms is connected to the midpoint J₂₁, and J₂₂ respectively of a second arm, via a load composed of two actuators I₁, I₂ and I₃, I₄ respectively, alternately connected in parallel with a load inductor L₁ and L₂ respectively. According to FIG. 6, two actuators are connected to a resonance inductor by a relay R₁ or R₂, but it is possible to connect them by two alternately operable selection switches.

For actuators having double galvanic isolation, it is possible according to another version of the topology to invert the position of the actuators with that of the selection means.

To function, the injection computer operates the relay or switch corresponding to the actuator to be excited, such as I₁, and then, in a first phase, operates a bridge switch P₂ of the first arm connecting a terminal of the said actuator to terminal B₂ of the converter such that it closes, and also operates bridge switch P₃ of the second arm connecting the other terminal of the said actuator to terminal B₁ of the converter such that it closes. In a second phase, the operation of the switches is inverted to obtain a periodic signal for excitation of the oscillating circuit composed of the actuator and its resonance inductor. These two phases are repeated a large number of times during the injection period.

According to a second structure of the invention, the device for operating an ultrasonic piezoelectric actuator is provided with a DC-to-DC converter that delivers two direct-current output voltages vₛ₁, vₛ₂ between a common reference terminal Bₒ and two end terminals B₁, B₂, in parallel with which there is connected at least one bridge arm, composed of two alternately operable switches, the midpoint of the said arm being connected to reference terminal Bₒ by a load comprising at least one actuator in series with a resonance inductor. The three terminals B₀, B₁, B₂ may or may not be mounted at floating potential relative to the battery.

FIG. 7 shows a first embodiment according to this second structure, wherein the device is provided with an arm composed of two alternately operable switches P₁, P₂ in series, connected in parallel with the end output terminals B₁, B₂ of converter C, the midpoint J of the said arm being connected to reference terminal Bₒ by four actuators Iᵢ in parallel, where i is an integral number varying from 1 to 4, connected alternately in series with a resonance inductor L.

According to the version of FIG. 7, each of the four actuators Iᵢ, a first terminal of which is connected to midpoint J of the arm, is connected by its other terminal to resonance inductor L via an alternately operable selection switch K, the other terminal of inductor L being connected to reference terminal Bₒ of converter C. For actuators having double galvanic isolation, it is possible to invert the position of the actuators with that of the selection means.

According to another version, illustrated by the diagram of FIG. 8, it is possible that the four actuators Iᵢ, a first terminal of which is connected to midpoint J of the arm, are connected in pairs to two operable relays Rⱼ, where j varies from 1 to 2, each connected to an alternately operable selection switch Kⱼ, which themselves are connected to a first terminal of a resonance inductor L, the other terminal of which is connected to reference terminal Bₒ of converter C.

The functioning of this operating circuit according to the first version of FIG. 7 is the following, as a function of the operation of the different switches. The operating signal, transmitted by the injection computer in order to excite an injector Iᵢ, first causes the corresponding selection switch Kᵢ to close. Then, in a first phase, it simultaneously causes a first bridge switch P₂ to close and the second bridge switch P₁ to open, so that the voltage v₂ at the terminals of the oscillating circuit formed by the actuator and the associated inductor is equal to vₛ₂, and in a second phase it causes the said switches to change over to the inverse position, in order that the voltage v₂ is then equal to vₛ₁. These two phases are then repeated a large number of times during the injection period.

FIG. 9 shows a second embodiment according to this second structure, wherein the device is provided with two arms mounted in parallel, each composed of two alternately operable bridge switches P₁ⱼ, P₂ⱼ in series, the midpoint Jᵢ of the said arms being connected to reference terminal Bₒ by a load composed of two actuators Iᵢ in parallel, alternately connected in series with a resonance inductor Lⱼ, where j is an integral number varying from 1 to 2. In the case of this figure, each of the four actuators Iᵢ, a first terminal of which is connected to the midpoint Jⱼ of at least one first arm, is connected via its other terminal to resonance inductor Lⱼ via an alternately operable selection switch Kᵢ, the other terminal of the inductor being connected to reference terminal Bₒ of the converter.

According to another version of this embodiment, illustrated in FIG. 10, the four actuators Iᵢ, a first terminal of which is connected to the midpoint Jᵢ of at least one arm, are connected in pairs to two operable relays Rⱼ, each connected to a first terminal of a resonance inductor Lⱼ, the other terminal of which is connected to reference terminal Bₒ of the converter.

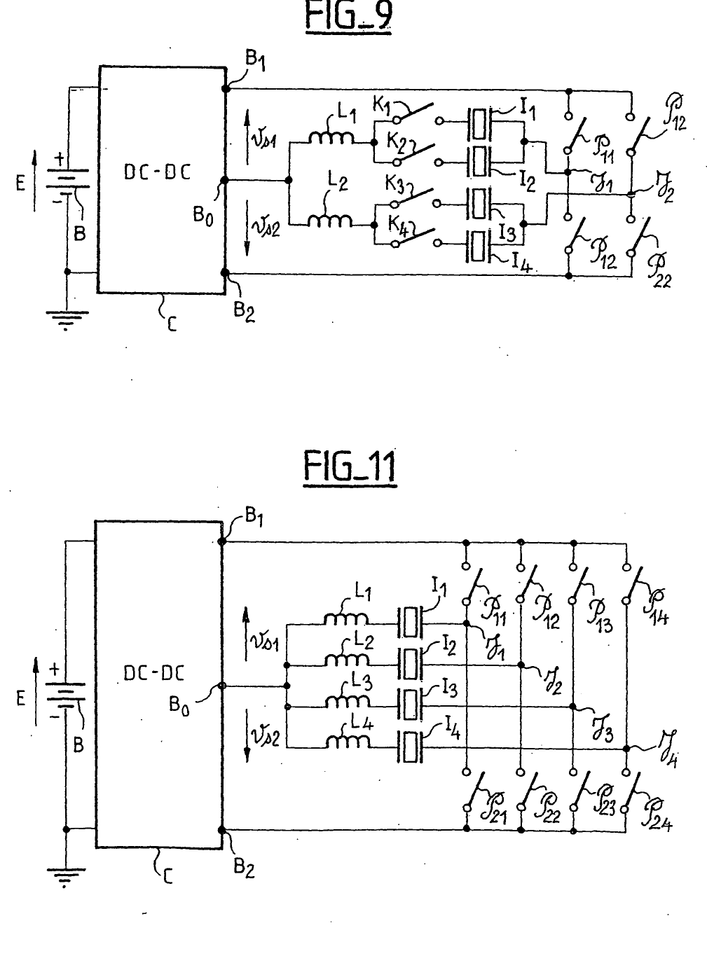

According to a third embodiment of this second structure, illustrated in FIG. 11, the operating device is provided with four arms, each composed of two alternately operable bridge switches P₁ᵢ, P₂ᵢ in series, mounted in parallel between the two end terminals B₁, B₂, the midpoint Jᵢ of which is connected to reference terminal Bₒ via a load composed of an actuator Iᵢ in series with a resonance inductor Lᵢ.

According to an essential characteristic of the invention, selection switches K of the actuators can be operated bidirectionally current-wise, and for that purpose can be constructed from two semiconductors mounted in series or in parallel. For example, they can be two transistors of the MOSFET type mounted in series.

Selection relays R of the actuators are of the monostable electromechanical type and have a break contact and a make contact.

As far as bridge switches P and P are concerned, if they are placed directly on the output side of the DC-to-DC converter, they are of the MOSFET, transistor or IGBT type, provided a diode is connected in anti-parallel manner in the latter case.

In all embodiments, the load inductor composing a resonant circuit with an injector is designed in such a way as to achieve the maximum resonance at the exciting frequency.

A second object of the invention is a method for use of a device for operating at least one ultrasonic piezoelectric actuator, such as described for the different foregoing topologies with the manner in which they function.

According to the first structure of the operating device, in which the DC-to-DC converter has a single output between two end terminals B₁ and B₂ and delivers a direct-current high voltage Vₛ, the method is characterized in that, for operation of a given actuator, the control computer on the one hand causes selection means connected to the said actuator to close and on the other hand, in a first phase, causes a first pair of bridge switches composed of a first switch of a first arm and of a second switch of a second arm to close and simultaneously the second pair formed from the other two switches of the said arms to open and, in a second phase, causes the said four switches to change over to an inverse position, in such a way as to obtain a sinusoidal voltage at the terminals of the oscillating circuit formed by the said actuator and the associated resonance inductor, these two phases being repeated a specified number of times during the period of functioning of the actuator in order to generate a high-voltage, high-frequency signal at the piezoelectric actuator from the direct-current voltage source.

According to the second structure of the device for operating an ultrasonic piezoelectric actuator, which is provided with a DC-to-DC converter that delivers two direct-current output voltages vₛ₁, vₛ₂ between a common reference terminal Bₒ and two end terminals B₁, B₂, the method is characterized in that, for operation of a given actuator, the control computer on the one hand causes selection means connected to the said actuator to close and on the other hand, in a first phase, causes a first bridge switch of a first arm to close and simultaneously the second switch to open and, in a second phase, causes the said two switches to change over to an inverse position, in such a way as to obtain a sinusoidal voltage at the terminals of the oscillating circuit formed by the said actuator and the associated resonance inductor, these two phases being repeated a specified number of times during the period of functioning of the actuator in order to generate a high-voltage, high-frequency signal at the piezoelectric actuator from the direct-current voltage source.

1-22. (Canceled).

23. A device for operating at least one ultrasonic piezoelectric actuator, which is driven electronically from a control computer and a direct-current voltage source, comprising:
a DC-to-DC converter fed by the voltage source and that delivers at least one direct-current output voltage between two end terminals; and
at least two bridge arms connected in parallel with the DC-to-DC converter, each including two alternately operable switches in series, midpoints of the arms being connected alternately to the two end terminals of the DC-to-DC converter by a load including at least one actuator in series with a resonance inductor.

24. A device for operating at least one ultrasonic piezoelectric actuator according to claim 23, wherein in a case in which the DC-to-DC converter delivers a single direct-current output voltage, the device is provided with at least one first bridge arm, composed of two alternately operable bridge switches, and with at least two second bridge arms, each including two alternately operable bridge switches and mounted in parallel with the first arm between the two end terminals of the DC-to-DC converter, such that a midpoint of each first arm is connected to a midpoint of at least one second arm by a load including at least one actuator connected to a resonance inductor.

25. A device for operating at least one ultrasonic piezoelectric actuator according to claim 24, wherein in a case in which the DC-to-DC converter delivers a single direct-current output voltage, the device is provided with two first bridge arms, mounted in parallel between the two end terminals of the DC-to-DC converter and each including two alternately operable bridge switches, and with two second bridge arms, each including two bridge switches respectively, such that a midpoint of each of the first arms is connected to a midpoint of a second arm, by a load including two actuators in parallel, connected alternately to a load inductor.

26. A device for operating at least one ultrasonic piezoelectric actuator according to claim 24, wherein in a case in which the DC-to-DC converter delivers a single direct-current output voltage, the device is provided with a first bridge arm, mounted in parallel between the two end terminals of the DC-to-DC converter and including two alternately operable bridge switches, and with two second bridge arms, including two bridge switches respectively, such that a midpoint of the first arm is connected to a midpoint of a second arm, by a load including two actuators in parallel, connected alternately to a load inductor.

27. A device for operating at least one ultrasonic piezoelectric actuator according to claim 24, wherein in a case in which the DC-to-DC converter delivers a single direct-current output voltage, the device is provided with a first bridge arm, mounted in parallel between the two end terminals of the DC-to-DC converter and including two alternately operable bridge switches, and with four second bridge arms, including two bridge switches respectively, such that a midpoint of the first arm is connected to a midpoint of a second arm, by a load including an actuator connected to a load inductor.

28. A device for operating at least one ultrasonic piezoelectric actuator according to claim 23, wherein in a case in which the DC-to-DC converter delivers a single direct-current output voltage, the device is provided with a first bridge arm, including two alternately operable bridge switches and connected in parallel with output terminals of the DC-to-DC converter, a midpoint of the first arm being connected to a midpoint of a second bridge arm, including two alternately operable switches and mounted in parallel with the first arm, by a load comprising four actuators in parallel, connected alternately to a resonance inductor.

29. A device for operating at least one ultrasonic piezoelectric actuator according to claim 28, wherein each of the four actuators, a first terminal of which is connected to a midpoint of one of the first and second arms mounted in parallel, is connected by its other terminal to a terminal of the resonance inductor by an alternately operable selection switch, the other terminal of the inductor being connected to a midpoint of the other arm.

30. A device for operating at least one ultrasonic piezoelectric actuator according to claim 28, wherein the actuators, a first terminal of which is connected to a midpoint of one of the first and second arms mounted in parallel, are connected in pairs to an operable relay, which is connected to an alternately operable selection switch, the switch itself being connected to a first terminal of a resonance inductor, the other terminal of which is connected to the midpoint of the other arm.

31. A device for operating at least one ultrasonic piezoelectric actuator according to claim 25, wherein the load connects the midpoint of the first arm to the midpoint of the second arm, mounted in parallel, and includes two actuators in parallel connected to a relay, the relay itself being connected to a resonance inductor.

32. A device for operating at least one ultrasonic piezoelectric actuator according to claim 25, wherein the load connects the midpoint of the first arm to the midpoint of the second arm, mounted in parallel, and includes two actuators in parallel and each connected to an operable selection switch, the switch itself being connected to a resonance inductor.

33. A device for operating at least one ultrasonic piezoelectric actuator according to claim 23, wherein in a case in which the DC-to-DC converter delivers two direct-current output voltages, the device is provided with two bridge arms in parallel, each including two alternately operable bridge switches, a midpoint of the arms being connected to a reference terminal by a load including two actuators in parallel, alternately connected in series with a resonance inductor.

34. A device for operating at least one ultrasonic piezoelectric actuator according to claim 33, wherein each of the four actuators, a first terminal of which is connected to the midpoint of at least one bridge arm, is connected by its other terminal to the resonance inductor by an alternately operable selection switch, the other terminal of the inductor being connected to a reference terminal of the converter.

35. A device for operating at least one ultrasonic piezoelectric actuator according to claim 33, wherein the four actuators, a first terminal of which is connected to the midpoint of at least one bridge arm, are connected in pairs to two operable relays, each connected to a first terminal of a resonance inductor, the other terminal of which is connected to a reference terminal of the DC-to-DC converter.

36. A device for operating at least one ultrasonic piezoelectric actuator according to claim 33, wherein the four actuators, a first terminal of which is connected to the midpoint of at least one bridge arm, are connected in pairs to two operable relays, each connected to an alternately operable selection switch, themselves connected to a first terminal of a resonance inductor, the other terminal of which is connected to a reference terminal of the converter.

37. A device for operating at least one ultrasonic piezoelectric actuator according to claim 33, wherein in a case in which the DC-to-DC converter delivers two direct-current output voltages the device is provided with four bridge arms, each including two alternately operable bridge switches mounted in parallel between the two end terminals, a midpoint of which is connected to a reference terminal by a load including an actuator in series with a resonance inductor.

38. A device for operating at least one ultrasonic piezoelectric actuator according to claim 23, wherein the voltage source is a low-voltage battery or an alternator.

39. A device for operating at least one ultrasonic piezoelectric actuator according to claim 23, wherein the selection switches of the actuators are configured to be operated bidirectionally current-wise, and are constructed from two semiconductors mounted in series or in parallel.

40. A device for operating at least one ultrasonic piezoelectric actuator according to claim 23, wherein the selection relays of the actuators are of the monostable electromechanical type and have a break contact and a make contact.

41. A device for operating at least one ultrasonic piezoelectric actuator according to claim 23, wherein the bridge switches are placed directly on an output side of the DC-to-DC converter, and are of MOSFET or IGBT or transistor type.

42. A method for use of a device for operating at least one ultrasonic piezoelectric actuator according to claim 23, wherein for operation of a given actuator, a control computer causes a selector connected to the actuator to close and, in a first phase, causes a first pair of bridge switches including a first switch of a first arm and of a second switch of a second arm to close and simultaneously the second pair formed from the other two switches of the arms to open and, in a second phase, causes the four switches to change over to an inverse position, to obtain a sinusoidal voltage at terminals of an oscillating circuit formed by the actuator and an associated resonance inductor, the two phases being repeated a specified number of times during a period of functioning of the actuator to generate a high-voltage, high-frequency signal at the actuator from the direct-current voltage source.

43. A method for use of a device for operating at least one ultrasonic piezoelectric actuator according to claim 23, for operation of a given actuator, a control computer causes a selector connected to the actuator to close and, in a first phase, causes a first bridge switch of a first arm to close and simultaneously the second switch to open and, in a second phase, causes the two switches to change over to an inverse position, to obtain a sinusoidal voltage at terminals of an oscillating circuit formed by the actuator and an associated resonance inductor, the two phases being repeated a specified number of times during a period of functioning of the actuator to generate a high-voltage, high-frequency signal at the actuator from the direct-current voltage source.
